(19) United States
(12) Patent Application Publication
(10) Pub. No.: US 2024/0312777 A1
(43) Pub. Date: Sep. 19, 2024

(54) METHOD OF PROCESSING SUBSTRATE, METHOD OF MANUFACTURING SEMICONDUCTOR DEVICE, RECORDING MEDIUM, AND SUBSTRATE PROCESSING APPARATUS

(71) Applicant: Kokusai Electric Corporation, Tokyo (JP)

(72) Inventors: Shingo NOHARA, Toyama-shi (JP); Kiyohisa Ishibashi, Toyama-shi (JP)

(73) Assignee: Kokusai Electric Corporation, Tokyo (JP)

(21) Appl. No.: 18/594,675

(22) Filed: Mar. 4, 2024

(30) Foreign Application Priority Data
Mar. 15, 2023 (JP) 2023-041326

(51) Int. Cl. H01L 21/02; C23C 16/34; C23C 16/40; C23C 16/455; C23C 16/52

(52) U.S. Cl. CPC H01L 21/0228; C23C 16/345; C23C 16/401; C23C 16/45534; C23C 16/52; H01L 21/02164; H01L 21/0217; H01L 21/02312

(57) ABSTRACT

There is provided a technique that includes: forming a film containing a predetermined element over an inner surface of a recess formed on a surface of a substrate by performing a cycle a predetermined number of times, the cycle including performing: (a) supplying a first modifying agent containing a first halogen element to the substrate; (b) supplying a second modifying agent containing a second halogen element, which is different in molecular structure from the first modifying agent, to the substrate; (c) after starting (a) and (b), forming a deposited layer containing the predetermined element by supplying a precursor containing the predetermined element, which is different in molecular structure from the first modifying agent and the second modifying agent, to the substrate; and (d) after (c), supplying a reactant, which reacts with the deposited layer, to the substrate.

### CROSS-REFERENCE TO RELATED APPLICATION

This application is based upon and claims the benefit of priority from Japanese Patent Application No. 2023-041326, filed on Mar. 15, 2023, the entire contents of which are incorporated herein by reference.

### TECHNICAL FIELD

The present disclosure relates to a method of processing a substrate, a method of manufacturing a semiconductor device, a recording medium, and a substrate processing apparatus.

### BACKGROUND

In the related art, as a process of manufacturing a semiconductor device, a process of forming a film over a substrate including a recess may be carried out.

### SUMMARY

Some embodiments of the present disclosure provide a technique capable of improving a step coverage of a film formed over a substrate.

According to some embodiments of the present disclosure, there is provide a technique that includes: forming a film containing a predetermined element over an inner surface of a recess formed on a surface of a substrate by performing a cycle a predetermined number of times, the cycle including performing: (a) supplying a first modifying agent containing a first halogen element to the substrate; (b) supplying a second modifying agent containing a second halogen element, which is different in molecular structure from the first modifying agent, to the substrate; (c) after starting (a) and (b), forming a deposited layer containing the predetermined element by supplying a precursor containing the predetermined element, which is different in molecular structure from the first modifying agent and the second modifying agent, to the substrate; and (d) after (c), supplying a reactant, which reacts with the deposited layer, to the substrate.

### BRIEF DESCRIPTION OF DRAWINGS

The accompanying drawings, which are incorporated in and constitute a part of the specification, illustrate embodiments of the present disclosure.

FIG. 1 is a schematic configuration view of a vertical process furnace of a substrate processing apparatus suitably used in embodiments of the present disclosure, in which a portion of the process furnace 202 is shown in a vertical cross section.

FIG. 2 is a schematic configuration view of the vertical process furnace of the substrate processing apparatus suitably used in the embodiments of the present disclosure, in which a portion of the process furnace 202 is shown in a cross section taken along line A-A in FIG. 1.

FIG. 3 is a schematic configuration diagram of a controller 121 of the substrate processing apparatus suitably used in the embodiments of the present disclosure, in which a control system of the controller 121 is shown in a block diagram.

FIG. 4 is a diagram showing a processing sequence according to embodiments of the present disclosure.

FIG. 5A is a view showing adsorption locations of a first modifying agent, which is supplied to a wafer, in a recess of the wafer. FIG. 5B is a view showing adsorption locations of a second modifying agent, which is supplied to the wafer after the supply of the first modifying agent is started, in the recess of the wafer. FIG. 5C is a view showing adsorption locations of a precursor, which is supplied to the wafer after the supply of the second modifying agent is started, in the recess of the wafer. FIG. 5D is a view showing a film formed in the recess of the wafer by performing a cycle a predetermined number of times, the cycle including a first modifying agent supplying step, a second modifying agent supplying step, a precursor supplying step, and a reactant supplying step.

FIG. 6 is a diagram showing a processing sequence according to a first modification of the present disclosure.

FIG. 7 is a diagram showing a processing sequence according to a second modification of the present disclosure.

FIG. 8 is a diagram showing a processing sequence according to a third modification of the present disclosure.

FIG. 9 is a diagram showing a processing sequence according to a fourth modification of the present disclosure.

FIG. 10 is a diagram showing a processing sequence according to a fifth modification of the present disclosure.

### DETAILED DESCRIPTION

Reference will now be made in detail to various embodiments, examples of which are illustrated in the accompanying drawings. In the following detailed description, numerous specific details are set forth to provide a thorough understanding of the present disclosure. However, it will be apparent to one of ordinary skill in the art that the present disclosure may be practiced without these specific details. In other instances, well-known methods, procedures, systems, and components are not described in detail so as not to obscure aspects of the various embodiments.

### Embodiments of the Present Disclosure

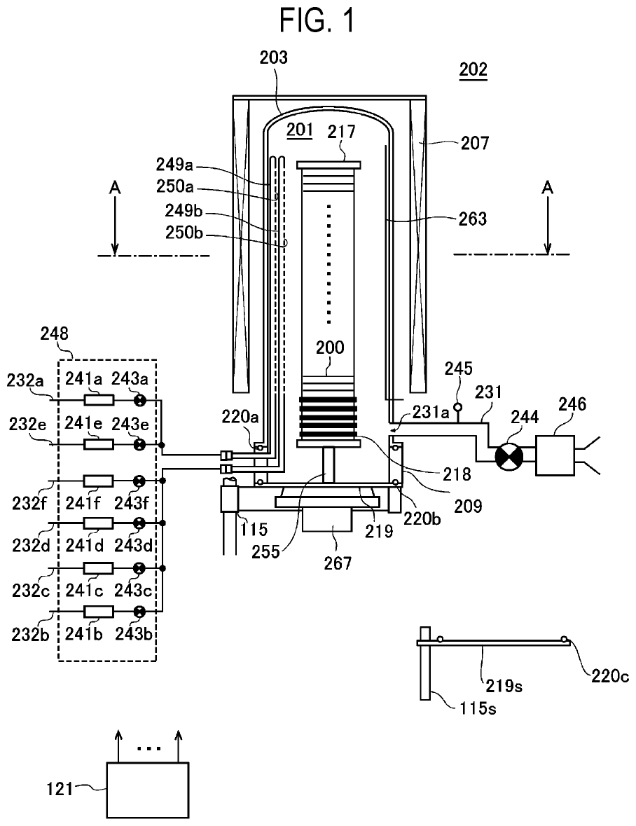

Embodiments of the present disclosure will now be described mainly with reference to FIGS. 1 to 4 and 5A to 5D. The drawings used in the following description are schematic, and dimensional relationships, ratios, and the like of various elements shown in figures may not match actual ones. Further, dimensional relationships, ratios, and the like of various elements between figures may not match each other.

### (1) Configuration of Substrate Processing Apparatus

As shown in FIG. 1, a process furnace 202 includes a heater 207 as a temperature regulator (a heating part). The heater 207 is formed in a cylindrical shape and is supported by a holding plate to be vertically installed. The heater 207 also functions as an activator (an exciter) configured to thermally activate (excite) a gas.

A reaction tube 203 is disposed inside the heater 207 to be concentric with the heater 207. The reaction tube 203 is made of, for example, a heat resistant material such as quartz (SiO₂) or silicon carbide (SiC), and is formed in a cylindrical shape with its upper end closed and its lower end opened. A manifold 209 is disposed to be concentric with the reaction tube 203 under the reaction tube 203. The manifold 209 is made of, for example, a metal material such as stainless steel (SUS), and is formed in a cylindrical shape with both of its upper and lower ends opened. The upper end of the manifold 209 engages with the lower end of the reaction tube 203 to support the reaction tube 203. An O-ring 220a serving as a seal is provided between the manifold 209 and the reaction tube 203. Similar to the heater 207, the reaction tube 203 is vertically installed. A process container (reaction container) mainly includes the reaction tube 203 and the manifold 209. A process chamber 201 is formed in a hollow cylindrical area of the process container. The process chamber 201 is configured to be capable of accommodating wafers 200 as substrates. The wafers 200 are processed in the process chamber 201.

Nozzles 249a and 249b as first and second suppliers are installed in the process chamber 201 to penetrate a sidewall of the manifold 209. The nozzles 249a and 249b are also referred to as first and second nozzles, respectively. The nozzles 249a and 249b are made of, for example, a heat resistant material such as quartz or SiC. The nozzles 249a and 249b are each constituted as a shared nozzle used to supply multiple types of gases.

Gas supply pipes 232a and 232b as first and second pipes are connected to the nozzles 249a and 249b, respectively. The gas supply pipes 232a and 232b are each constituted as a shared pipe used to supply multiple types of gases. Mass flow controllers (MFCs) 241a and 241b, which are flow rate controllers (flow rate control parts), and valves 243a and 243b, which are opening/closing valves, are installed at the gas supply pipes 232a and 232b, respectively, sequentially from the upstream side of a gas flow. A gas supply pipe 232e is connected to the gas supply pipe 232a at the downstream side of the valves 243a. A MFC 241e and a valve 243e are installed at the gas supply pipe 232e sequentially from the upstream side of a gas flow. Gas supply pipes 232c, 232d, and 232f are each connected to the gas supply pipe 232b at the downstream side of the valves 243b. MFCs 241c, 241d, and 241f and valves 243c, 243d, and 243f are installed at the gas supply pipes 232c, 232d, and 232f, respectively, sequentially from the upstream side of a gas flow. The gas supply pipes 232a to 232f are made of, for example, a metal material such as SUS.

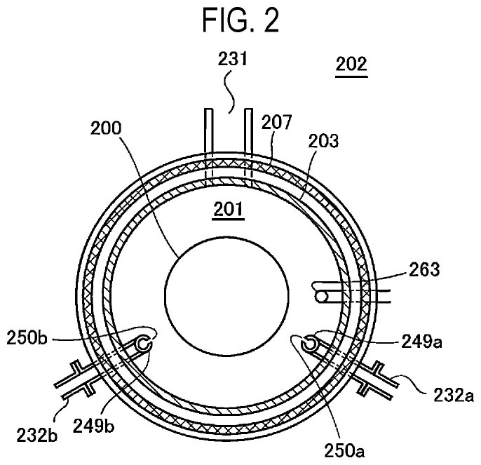

As shown in FIG. 2, each of the nozzles 249a and 249b is installed in an annular space (in a plane view) between an inner wall of the reaction tube 203 and the wafers 200 to extend upward from a lower side to an upper side of the inner wall of the reaction tube 203, that is, along an arrangement direction of the wafers 200. Specifically, each of the nozzles 249a and 249b is installed in a region horizontally surrounding a wafer arrangement region in which the wafers 200 are arranged at a lateral side of the wafer arrangement region, along the wafer arrangement region. Gas supply holes 250a and 250b configured to supply gases are formed on side surfaces of the nozzles 249a and 249b, respectively. Each of the gas supply holes 250a and 250b is opened to face the centers of the wafers 200 in the plane view, thereby making it possible to supply the gases toward the wafers 200. A plurality of gas supply holes 250a and 250b are formed from the lower side to the upper side of the reaction tube 203.

A reactant as a pretreatment agent and a film-forming agent is supplied from the gas supply pipe 232a into the process chamber 201 via the MFC 241a, the valve 243a, and the nozzle 249a.

A first modifying agent is supplied from the gas supply pipe 232b into the process chamber 201 via the MFC 241b, the valve 243b, and the nozzle 249b.

A second modifying agent is supplied from the gas supply pipe 232c into the process chamber 201 via the MFC 241c, the valve 243c, and the nozzle 249b.

A precursor as a film-forming agent is supplied from the gas supply pipe 232d into the process chamber 201 via the MFC 241d, the valve 243d, and the nozzle 249b.

An inert gas is supplied from the gas supply pipes 232e and 232f into the process chamber 201 via the MFCs 241e and 241f, the valves 243e and 243f, the gas supply pipes 232a and 232b, and the nozzles 249a and 249b, respectively. The inert gas acts as a purge gas, a carrier gas, a dilution gas, or the like.

A reactant supply system mainly includes the gas supply pipe 232a, the MFC 241a, and the valve 243a. A first modifying agent supply system mainly includes the gas supply pipe 232b, the MFC 241b, and the valve 243b. A second modifying agent supply system mainly includes the gas supply pipe 232c, the MFC 241c, and the valve 243c. A precursor supply system mainly includes the gas supply pipe 232d, the MFC 241d, and the valve 243d. An inert gas supply system mainly includes the gas supply pipes 232e and 232f, the MFCs 241e and 241f, and the valves 243e and 243f. The nozzles connected to the gas supply pipes constituting the above-described various supply systems may be included in the supply systems, respectively.

One or the entirety of the above-described various supply systems may be constituted as an integrated supply system 248 in which the valves 243a to 243f, the MFCs 241a to 241f, and so on are integrated. The integrated supply system 248 is connected to each of the gas supply pipes 232a to 232f, and is configured such that operations of supplying various substances (various gases) into the gas supply pipes 232a to 232f (that is, the opening/closing operation of the valves 243a to 243f, the flow rate regulation operation by the MFCs 241a to 241f, and the like) are controlled by a controller 121 described below. The integrated supply system 248 is constituted as an integral or detachable integrated unit, and may be attached to or detached from the gas supply pipes 232a to 232f and the like on an integrated unit basis, such that maintenance, replacement, extension, and the like of the integrated supply system 248 may be performed on an integrated unit basis.

An exhaust port 231a configured to exhaust an internal atmosphere of the process chamber 201 is installed below the sidewall of the reaction tube 203. As shown in FIG. 2, in the plane view, the exhaust port 231a is installed at a position opposing (facing) the nozzles 249a and 249b (the gas supply holes 250a and 250b) with the wafers 200 therebetween. The exhaust port 231a may be installed from a lower side to an upper side of the sidewall of the reaction tube 203, that is, along the wafer arrangement region. An exhaust pipe 231 is connected to the exhaust port 231a. A vacuum pump 246 as a vacuum exhauster is connected to the exhaust pipe 231 via a pressure sensor 245, which is a pressure detector (pressure detection part) configured to detect the internal pressure of the process chamber 201, and an auto pressure controller (APC) valve 244, which is a pressure regulator (pressure regulation part). The APC valve 244 is configured to be capable of performing or stopping a vacuum exhaust operation in the process chamber 201 by opening/closing the valve while the vacuum pump 246 is actuated, and is also configured to be capable of regulating the internal pressure of the process chamber 201 by adjusting an opening state of the valve based on pressure information detected by the pressure sensor 245 while the vacuum pump 246 is actuated. An exhaust system mainly includes the exhaust pipe 231, the APC valve 244, and the pressure sensor 245. The exhaust system may include the vacuum pump 246.

A seal cap 219, which serves as a furnace opening lid configured to be capable of hermetically sealing a lower end opening of the manifold 209, is installed under the manifold 209. The seal cap 219 is made of, for example, a metal material such as SUS, and is formed in a disc shape. An O-ring 220b, which is a seal making contact with the lower end of the manifold 209, is installed on an upper surface of the seal cap 219. A rotator 267 configured to rotate a boat 217 described below, is installed under the seal cap 219. A rotary shaft 255 of the rotator 267 is connected to the boat 217 through the seal cap 219. The rotator 267 is configured to rotate the wafers 200 by rotating the boat 217. The seal cap 219 is configured to be vertically moved up or down by a boat elevator 115 which is an elevator installed outside the reaction tube 203. The boat elevator 115 is constituted as a transporter (transport mechanism) configured to load or unload (transport) the wafers 200 into or out of the process chamber 201 by moving the seal cap 219 up or down.

A shutter 219s, which serves as a furnace opening lid configured to be capable of hermetically sealing a lower end opening of the manifold 209 in a state where the seal cap 219 is lowered and the boat 217 is unloaded from the process chamber 201, is installed under the manifold 209. The shutter 219s is made of, for example, a metal material such as SUS, and is formed in a disc shape. An O-ring 220c, which is a seal making contact with the lower end of the manifold 209, is installed on an upper surface of the shutter 219s. The opening/closing operation (such as elevation operation, rotation operation, or the like) of the shutter 219s is controlled by a shutter opening/closing mechanism 115s.

The boat 217 serving as a substrate support is configured to support a plurality of wafers 200, for example, 25 to 200 wafers, in such a state that the wafers 200 are arranged in a horizontal posture and in multiple stages along a vertical direction with the centers of the wafers 200 aligned with one another. That is, the boat 217 is configured to arrange the wafers 200 to be spaced apart from each other. The boat 217 is made of, for example, a heat resistant material such as quartz or SiC. Heat insulating plates 218 made of, for example, a heat resistant material such as quartz or SiC are installed below the boat 217 in multiple stages.

A temperature sensor 263 serving as a temperature detector is installed in the reaction tube 203. Based on temperature information detected by the temperature sensor 263, a state of supplying electric power to the heater 207 is regulated such that a temperature distribution inside the process chamber 201 becomes a desired temperature distribution. The temperature sensor 263 is installed along the inner wall of the reaction tube 203.

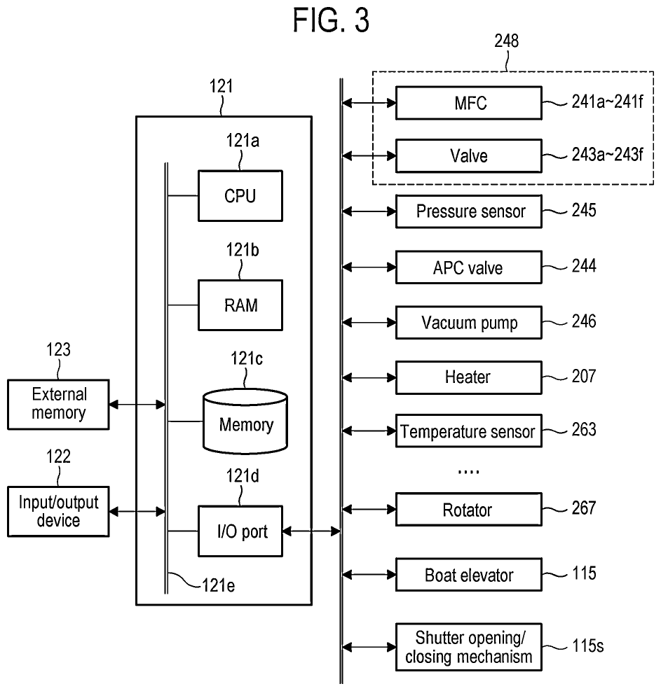

As shown in FIG. 3, a controller 121, which is a control part (control means or unit), is constituted as a computer including a central processing unit (CPU) 121a, a random access memory (RAM) 121b, a memory 121c, and an I/O port 121d. The RAM 121b, the memory 121c, and the I/O port 121d are configured to be capable of exchanging data with the CPU 121a via an internal bus 121e. An input/output device 122 including, e.g., a touch panel or the like, is connected to the controller 121. Further, an external memory 123 may be connected to the controller 121. A substrate processing apparatus may be configured to include one controller, or may be configured to include a plurality of controllers. That is, a control of performing a processing sequence described below may be performed by using one controller, or may be performed by using a plurality of controllers. Further, the plurality of controllers may be constituted as a control system in which the controllers are connected to one another via a wired or wireless communication network, and the entire control system may perform a control of performing the processing sequence described below. When the term “controller” is used in the present disclosure, it may include a case of including one controller, a case of including a plurality of controllers, or a case of including a control system constituted by the plurality of controllers.

The memory 121c includes, for example, a flash memory, a hard disk drive (HDD), a solid state drive (SSD), or the like. A control program that controls operations of a substrate processing apparatus, a process recipe in which sequences and conditions of substrate processing described below are written, and the like are readably recorded and stored in the memory 121c. The process recipe functions as a program configured to cause, by the controller 121, the substrate processing apparatus to execute each sequence in the substrate processing described below, to obtain an expected result. Hereinafter, the process recipe and the control program may be generally and simply referred to as a “program.” Furthermore, the process recipe may be simply referred to as a “recipe.” When the term “program” is used herein, it may indicate a case of including the recipe, a case of including the control program, or a case of including both the recipe and the control program. The RAM 121b is constituted as a memory area (work area) in which programs or data read by the CPU 121a are temporarily stored.

The I/O port 121d is connected to the MFCs 241a to 241f, the valves 243a to 243f, the pressure sensor 245, the APC valve 244, the vacuum pump 246, the temperature sensor 263, the heater 207, the rotator 267, the boat elevator 115, the shutter opening/closing mechanism 115s, and so on.

The CPU 121a is configured to be capable of reading and executing the control program from the memory 121c. The CPU 121a is also configured to be capable of reading the recipe from the memory 121c according to an input of an operation command from the input/output device 122. The CPU 121a is configured to be capable of controlling flow rate regulation operations of various kinds of substances (various kinds of gases) by the MFCs 241a to 241f, opening/closing operations of the valves 243a to 243f, an opening/closing operation of the APC valve 244, a pressure regulation operation performed by the APC valve 244 based on the pressure sensor 245, actuating and stopping operations of the vacuum pump 246, a temperature regulation operation performed by the heater 207 based on the temperature sensor 263, operations of rotating the boat 217 and adjusting a rotation speed of the boat 217 with the rotator 267 and an operation of, an operation of moving the boat 217 up or down by the boat elevator 115, an opening/closing operation of the shutter 219s by the shutter opening/closing mechanism 115s, and so on, according to contents of the read recipe.

The controller 121 may be constituted by installing, on the computer, the above-described program recorded and stored in the external memory 123. Examples of the external memory 123 may include a magnetic disk such as a HDD, an optical disc such as a CD, a magneto-optical disc such as a MO, a semiconductor memory such as a USB memory or a SSD, and the like. The memory 121c or the external memory 123 is constituted as a computer-readable recording medium. Hereinafter, the memory 121c and the external memory 123 may be generally and simply referred to as a “recording medium.” When the term “recording medium” is used herein, it may indicate a case of including the memory 121c, a case of including the external memory 123, or a case of including both the memory 121c and the external memory 123. Further, the program may be provided to the computer by using communication means or unit such as the Internet or a dedicated line, instead of using the external memory 123.

### (2) Substrate Processing Process

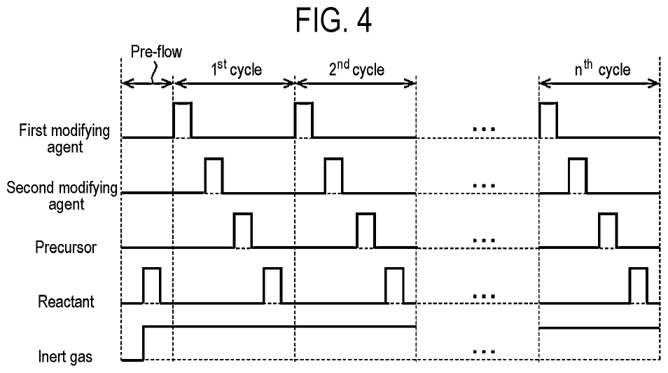

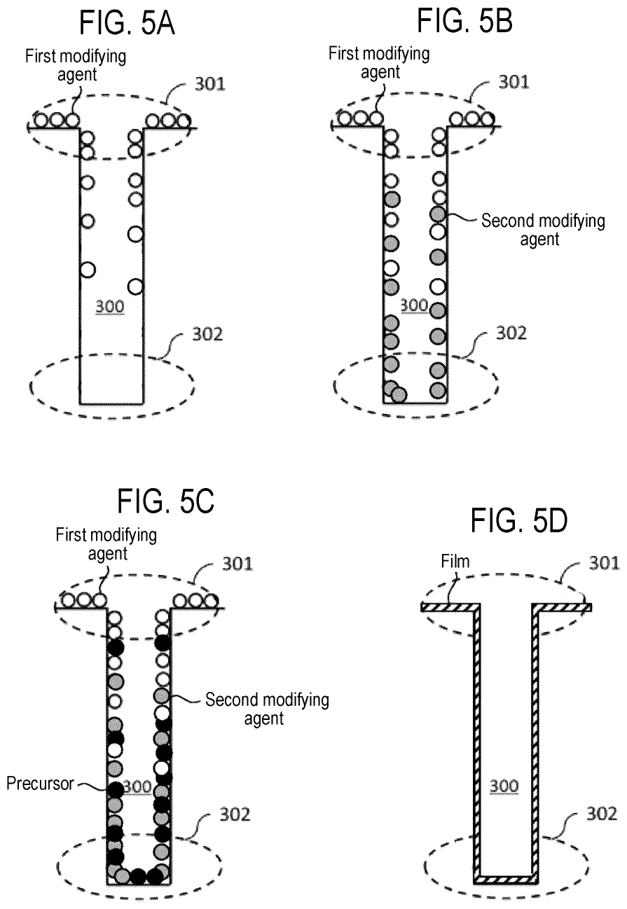

As a process of manufacturing a semiconductor device using the above-described substrate processing apparatus, an example of a method of processing a substrate, that is, a processing sequence of forming a film over a wafer 200 as a substrate on which a recess 300, such as a trench, a groove, and a hole, with a three-dimensional structure is formed will be described mainly with reference to FIGS. 4 and 5A to 5D. In the following description, operations of the respective components constituting the substrate processing apparatus are controlled by the controller 121.

A processing sequence in the embodiments of the present disclosure includes:
forming a film containing a predetermined element over an inner surface of a recess 300, with a three-dimensional structure, formed on a surface of a wafer 200 by performing a cycle a predetermined number of times (n times, where n is an integer of 1 or 2 or more), the cycle including performing:
(a) step A of supplying a first modifying agent containing a first halogen element to the wafer 200;
(b) step B of supplying a second modifying agent containing a second halogen element, which is different in molecular structure from the first modifying agent, to the wafer 200;
(c) after starting (a) and (b), step C of forming a deposited layer containing the predetermined element over the inner surface of the recess 300 by supplying a precursor containing the predetermined element, which is different in molecular structure from the first modifying agent and the second modifying agent, to the wafer 200; and
(d) after (c), step D of supplying a reactant, which reacts with the deposited layer, to the wafer 200.

In the embodiments, the predetermined element contained in the precursor is a main element constituting the deposited layer and the film formed over the wafer 200. Hereinafter, as an example, a case will be described in which the predetermined element is silicon (Si) and a Si film is formed as a base on the surface of the wafer 200.

In the processing sequence in the embodiments, as shown in FIG. 4, a step (pre-flow) of supplying a reactant to the wafer 200 is further performed before forming the film.

In the present disclosure, for the sake of convenience, the above-described processing sequence may be denoted as follows. The same denotation may be used in modifications and other embodiments described below.

Pretreatment reactant (pre-flow)→(First modifying agent→Purge→Second modifying agent→Purge→Precursor→Purge→Reactant→Purge)×n

When the term “wafer” is used in the present disclosure, it may refer to “a wafer itself” or “a stacked body of a wafer and certain layers or films formed on a surface of the wafer.” When the phrase “a surface of a wafer” is used in the present disclosure, it may refer to “a surface of a wafer itself” or “a surface of a certain layer formed on a wafer.” When the expression “a certain layer is formed on a wafer” is used in the present disclosure, it may mean that “a certain layer is formed directly on a surface of a wafer itself” or that “a certain layer is formed on a layer formed on a wafer.” When the term “substrate” is used in the present disclosure, it may be synonymous with the term “wafer,”

The term “agent” used in the present disclosure includes at least one selected from the group of a gaseous substance and a liquefied substance. The liquefied substance includes a misty substance. That is, each of the first modifying agent, the second modifying agent, the precursor, and the reactant may include a gaseous substance, a liquefied substance such as a misty substance, or both of them.

The term “layer” used in the present disclosure includes at least one selected from the group of a continuous layer and a discontinuous layer. For example, the deposited layer may include a continuous layer, a discontinuous layer, or both of them.

In the present disclosure, when it is mentioned that the first modifying agent, the second modifying agent, the precursor, and the reactant are each adsorbed on or react with the surface of the wafer, it may include an aspect in which they are adsorbed on or react with the surface of the wafer while remaining undecomposed, and an aspect in which intermediates generated when they are decomposed or their ligands are desorbed are adsorbed on or react with the surface of the wafer.

### (Wafer Charging and Boat Loading)

After the boat 217 is charged with a plurality of wafers 200 (wafer charging), the shutter 219s is moved by the shutter opening/closing mechanism 115s to open the lower end opening of the manifold 209 (shutter opening). Thereafter, as shown in FIG. 1, the boat 217 supporting the plurality of wafers 200 is lifted by the boat elevator 115 to be loaded into the process chamber 201 (boat loading). In this state, the seal cap 219 seals the lower end of the manifold 209 via the O-ring 220b. Thus, the wafers 200 are prepared inside the process chamber 201.

### (Pressure Regulation and Temperature Regulation)

After the boat loading is completed, an inside of the process chamber 201, that is, a space where the wafers 200 are placed, is vacuum-exhausted (decompression-exhausted) by the vacuum pump 246 to reach a desired pressure (state of vacuum). At this time, the internal pressure of the process chamber 201 is measured by the pressure sensor 245, and the APC valve 244 is feedback-controlled based on the measured pressure information. Further, the wafers 200 in the process chamber 201 are heated by the heater 207 to reach a desired processing temperature. At this time, a state of supplying electric power to the heater 207 is feedback-controlled based on the temperature information detected by the temperature sensor 263 such that a temperature distribution inside the process chamber 201 becomes a desired temperature distribution. Further, the rotation of the wafers 200 by the rotator 267 is started. The exhaust of the inside of the process chamber 201 and the heating and rotation of the wafers 200 are continuously performed at least until the processing on the wafers 200 is completed.

### (Film-Forming Process)

Thereafter, pre-flow and film formation are performed in this order.

### [Pre-Flow (Pretreatment)]

In this step, a pretreatment reactant as a pretreatment agent is supplied to a wafer 200 in the process chamber 201. In the embodiments of the present disclosure, a reactant used in step D described below, is also used as the pretreatment reactant.

Specifically, the valve 243a is opened to allow the reactant as the pretreatment reactant to flow through the gas supply pipe 232a. A flow rate of the reactant is regulated by the MFC 241a, and the reactant is supplied into the process chamber 201 via the nozzle 249a and is exhausted via the exhaust port 231a. In this operation, the reactant is supplied to the wafer 200 (supply of pretreatment reactant). At this time, the valves 243e and 243f may be opened to allow an inert gas to be supplied into the process chamber 201 via the nozzles 249a and 249b, respectively.

A process condition when the reactant is supplied in this step is exemplified as follows:
Processing temperature: 400 to 900 degrees C., specifically 500 to 900 degrees C., more specifically 600 to 750 degrees C.
Processing pressure: 1 to 4,000 Pa, specifically 20 to 1,333 Pa
Supply flow rate of reactant: 0.1 to 10 slm
Supply time of reactant: 5 to 1,800 seconds
Supply flow rate of inert gas (for each gas supply pipe): 0 to 10 slm

In the present disclosure, a notation of a numerical range such as “400 to 900 degrees C.” means that a lower limit value and an upper limit value thereof are included in the range. Therefore, for example, “400 to 900 degrees C.” means “400 degrees C. or higher and 900 degrees C. or lower.” The same applies to other numerical ranges. In the present disclosure, the processing temperature means a temperature of the wafer 200 or an internal temperature of the process chamber 201, and the processing pressure means an internal pressure of the process chamber 201. Further, the processing time means a time during which the processing is continued. Further, when 0 slm is included in the supply flow rate, 0 slm means a case where the substance (gas) is not supplied. These also hold true in the following description.

A native oxide film or the like may be formed on the surface of the wafer 200 before a film-forming process is performed. By supplying, for example, a hydrogen nitride-based gas containing nitrogen (N) and hydrogen (H) as the pretreatment reactant to the wafer 200 under the above-described process condition, it becomes possible to form NH termination (adsorption site by H) on the surface of the wafer 200 on which the native oxide film or the like is formed. This makes it possible to cause a desired film formation reaction to be efficiently performed on the wafer 200 in steps A to D described below.

As the reactant which is the pretreatment reactant, hydrogen nitride-based gases such as a diazene (N₂H₂) gas, a hydrazine (N₂H₄) gas, an ammonia (NH₃) gas, and a N₃H₅ gas may be used. One or more of these gases may be used as the reactant. This point also applies to a reactant as a film-forming agent used in step D described below.

As the inert gas, a nitrogen (N₂) gas or a rare gas such as an argon (Ar) gas, a helium (He) gas, a neon (Ne) gas, or a xenon (Xe) gas may be used. One or more of these gases may be used as the inert gas. This point also applies to each step described below.

After forming the NH termination (adsorption sites) on the inner surface of a recess 300 of the wafer 200, the valve 243a is closed to stop the supply of the reactant into the process chamber 201. Then, the inside of the process chamber 201 is vacuum-exhausted to remove a gaseous substance and the like remaining in the process chamber 201 from the inside of the process chamber 201. In this operation, the valves 243e and 243f are opened to allow an inert gas to be supplied into the process chamber 201 via the nozzles 249a and 249b, respectively. The inert gas supplied from the nozzles 249a and 249b acts as a purge gas, whereby the inside of the process chamber 201 is purged (purging).

### [Film Formation]

After the pre-flow is completed, film formation is performed. In this step, step A, step B, step C, and step D are performed in this order.

### Step A

In this step, a first modifying agent containing a first halogen element is supplied to the wafer 200 in the process chamber 201, that is, the wafer 200 after the adsorption sites are formed on the inner surface of the recess 300.

Specifically, the valve 243b is opened to allow the first modifying agent to flow through the gas supply pipe 232b. A flow rate of the first modifying agent is regulated by the MFC 241b, and the first modifying agent is supplied into the process chamber 201 via the nozzle 249b and is exhausted via the exhaust port 231a. In this operation, the first modifying agent is supplied to the wafer 200 (supply of first modifying agent). At this time, the valves 243e and 243f may be opened to allow an inert gas to be supplied into the process chamber 201 via the nozzles 249a and 249b, respectively.

A process condition when the first modifying agent is supplied in this step is exemplified as follows:
Processing temperature: 400 to 900 degrees C., specifically 500 to 800 degrees C., more specifically 600 to 750 degrees C.
Processing pressure: 1 to 2,666 Pa, specifically 10 to 1,333 Pa
Supply flow rate of first modifying agent: 0.001 to 3 slm, specifically 0.01 to 1 slm
Supply time of first modifying agent: 1 to 120 seconds, specifically 10 to 60 seconds

However, the supply time of first modifying agent may be shorter than a supply time of second modifying agent in step B. Other process conditions may be the same as those used when supplying the pretreatment reactant during the pre-flow. From the viewpoint of improving a processing speed, the processing temperature may be substantially the same temperature in any of steps A to D.

By supplying the first modifying agent containing the first halogen element to the wafer 200 under the above-described process condition, the first modifying agent may be adsorbed on the surface of the wafer 200 to form a first termination where the surface is terminated with the first halogen element (see FIG. 5A). A region on the surface of the wafer 200 where the first termination is formed (that is, a region where an adsorption layer of the first modifying agent is formed) is also referred to as a first termination region. Specifically, as a result, the first termination region, where the termination (first termination) of the first halogen element is discontinuously formed, may be formed on at least a portion of an upper surface of the recess 300, on at least a portion of an inner surface of the recess 300, or on at least both a portion of an upper surface and a portion of an inner surface of the recess 300 (specifically, side wall surfaces and a bottom surface inside the recess 300). More specifically, as a result, the first modifying agent may be adsorbed preferentially to an opening side 301 of the recess 300, thereby forming the first termination (see FIG. 5A). In other words, the first termination region is formed on at least a portion of the upper surface of the recess 300, on at least a portion of the inner surface of the recess 300, or on at least both a portion of the upper surface and a portion of the inner surface of the recess 300 such that a density of the first termination (that is, a density of the adsorption layer of the first modifying agent) increases from a deep side 302 toward the opening side 301 of the recess 300. The first termination region may be formed such that the first termination (that is, the adsorption layer of the first modifying agent) is discontinuously formed over the entire inner surface of the recess 300.

In the first termination region, adsorption of a second modifying agent and a precursor supplied in steps B and C described below, is suppressed by the first termination. The first termination is greater in adsorption suppressing effect on the precursor supplied in step C than the second termination formed in step B.

In the embodiments of the present disclosure, a gas that does not contain Si, which is a predetermined element, is used as the first modifying agent. By using the gas that does not contain the predetermined element as the first modifying agent and using a gas that contains the predetermined element as the second modifying agent, it becomes easy to make the adsorption suppressing effect of the first termination on the precursor supplied in step C greater than that of the second termination. On the other hand, by using the gas that does not contain the predetermined element as the first modifying agent and using the gas that contains the predetermined element as the second modifying agent, the first modifying agent tends to be lower in rate of adsorption on the surface of the wafer 200 than the second modifying agent. That is, in the embodiments, a gas being lower in rate of adsorption on the surface of the wafer 200 than the second modifying agent is used as the first modifying agent.

As the first modifying agent, a gas containing at least one selected from the group of chlorine (Cl), fluorine (F), bromine (Br), and iodine (I) as the first halogen element may be used. Examples of the first modifying agent may include gases composed of halogen elements such as a fluorine (F₂) gas, a chlorine (Cl₂) gas, a bromine (Br₂) gas, and an iodine (I₂) gas, inter-halogen compound gases such as a chlorine fluoride (ClF₃) gas, a bromine chloride (BrCl) gas, an iodine chloride (ICl) gas, an iodine fluoride (IF₅) gas, a bromine fluoride (BrF₃) gas, and an iodine bromide (IBr) gas, hydrogen halide compound gases such as a hydrogen chloride (HCl) gas, a hydrogen fluoride (HF) gas, a hydrogen bromide (HBr) gas, and a hydrogen iodide (HI) gas, or a combination of these gases. Further, radicals (Cl*, F*, Br*, I*, etc.) containing halogen elements, which are generated by activating these gases by plasma excitation or the like, may be used. One or more of these may be used as the first modifying agent. When using a gas containing a halogen element or a gas containing a halogen element and hydrogen, as described above, as the first modifying agent, these gases tend to corrode members such as the manifold 209 and the exhaust pipe 231 that may be made of metal materials. Therefore, as described above, the supply time of first modifying agent may be shorter than the supply time of second modifying agent to minimize damage to apparatus members.

After forming the first termination on the surface of the wafer 200 (the upper surface and inner surface of the recess 300), the valve 243b is closed to stop the supply of the first modifying agent into the process chamber 201. Then, the inside of the process chamber 201 is vacuum-exhausted to remove a gaseous substance and the like remaining in the process chamber 201 from the inside of the process chamber 201. At this time, the valves 243e and 243f are opened to allow an inert gas to be supplied into the process chamber 201 via the nozzles 249a and 249b, respectively. The inert gas supplied from the nozzles 249a and 249b acts as a purge gas, whereby a space where the wafer 200 is placed, that is, the inside of the process chamber 201, is purged (purging).

### Step B

After step A is completed, a second modifying agent containing a second halogen element is supplied to the wafer 200 in the process chamber 201, that is, the wafer 200 after the first termination region is formed on the inner surface of the recess 300.

Specifically, the valve 243c is opened to allow the second modifying agent to flow through the gas supply pipe 232c. A flow rate of the second modifying agent is regulated by the MFC 241c, and the second modifying agent is supplied into the process chamber 201 via the nozzle 249b and is exhausted via the exhaust port 231a. In this operation, the second modifying agent is supplied to the wafer 200 (supply of second modifying agent). At this time, the valves 243e and 243f may be opened to allow an inert gas to be supplied into the process chamber 201 via the nozzles 249a and 249b, respectively.

A process condition when the second modifying agent is supplied in this step is exemplified as follows:
Processing temperature: 400 to 900 degrees C., specifically 500 to 800 degrees C., more specifically 600 to 750 degrees C.
Processing pressure: 1 to 2,666 Pa, specifically 10 to 1,333 Pa
Supply flow rate of second modifying agent: 0.001 to 3 slm, specifically 0.01 to 1 slm
Supply time of second modifying agent: 10 to 300 seconds, specifically 30 to 120 seconds

However, the supply time of second modifying agent may be longer than the supply time of first modifying agent in step A. Other process conditions may be the same as those used when supplying the pretreatment reactant during the pre-flow.

By supplying the second modifying agent containing the second halogen element to the wafer 200 under the above-described process condition, the second modifying agent may be adsorbed on adsorption sites where the first modifying agent is not adsorbed, that is, locations where the first termination is not formed, of at least a portion of the upper surface, at least a portion of the inner surface, or at least both a portion of the upper surface and a portion of the inner surface of the recess 300, to form a second termination (a region where an adsorption layer of the second modifying agent is formed) terminated with the second halogen element (see FIG. 5B). A region on the surface of the wafer 200 where the second termination is formed (that is, the region where the adsorption layer of the second modifying agent is formed) is also referred to as a second termination region.

Specifically, as a result, the second modifying agent may be adsorbed on the adsorption sites where the first modifying agent is not adsorbed (the locations where the first termination is not formed), of at least a portion of the upper surface, at least a portion of the inner surface, or at least both a portion of the upper surface and a portion of the inner surface of the recess 300, to form the second termination region where the termination (the second termination) of the second halogen element is discontinuously formed (see FIG. 5B). In the second termination region, adsorption of a precursor supplied in step C, which is described below, is suppressed by the second termination.

In the embodiments of the present disclosure, on a surface of the deep side 302 including the bottom surface of the recess 300, a density of the second termination (that is, a density of the adsorption layer of the second modifying agent) in the second termination region is set to be higher than the density of the first termination (that is, the density of the adsorption layer of the first modifying agent) in the first termination region. Further, in step A, when the first termination region where the first termination (that is, the adsorption layer of the first modifying agent) is discontinuously formed is formed over the entire inner surface of the recess 300, step B may be performed such that the density of the second terminations in the second termination region is higher than that of the first termination region over the entire inner surface of the recess 300.

Further, as shown in FIG. 5B, the first termination region (the region where the adsorption layer of the first modifying agent is formed) terminated with the first halogen element and the second termination region (the region where the adsorption layer of the second modifying agent is formed) terminated with the second halogen element may at least partially overlap each other at the inner surface of the recess 300. In other words, the second termination may be formed for at least a portion of adsorption sites remaining in a gap between the discontinuously formed first terminations.

As the second modifying agent, a gas containing at least one selected from the group of Cl, F, Br, and I as the second halogen element may be used. The second halogen element of the second modifying agent and the first halogen element of the first modifying agent may be the same element or different elements. By using different elements for the first halogen element and the second halogen element, for example, an amount of a single halogen element remaining in a film may be reduced. As the second modifying agent, one or more of the gases exemplified in step A may be used. However, the second modifying agent is a gas which is different in molecular structure from the first modifying agent. Further, as the second modifying agent, a gas which is higher in rate of adsorption on the surface of the wafer 200 than the first modifying agent may be used.

Further, as the second modifying agent, a halogen-containing gas containing the second halogen element and a predetermined element may be used. More specifically, as the second modifying agent, halosilane-based gases containing the second halogen element and Si, such as a tetrachlorosilane (SiCl₄) gas, a monochlorosilane (SiH₃Cl) gas, a dichlorosilane (SiH₂Cl₂) gas, a trichlorosilane (SiHCl₃) gas, a tetrafluorosilane (SiF₄) gas, a trifluorosilane (SiHF₃) gas, a difluorosilane (SiH₂F₂) gas, a tetrabromosilane (SiBr₄) gas, a tribromosilane (SiHBr₃) gas, a dibromosilane (SiH₂Br₂) gas, a tetraiodosilane (SiI₄) gas, a triiodosilane (SiHI₃) gas, and a diiodosilane (SiH₂I₂) gas, which does not contain any Si—Si bond (that is, any bond between predetermined elements) in one molecule, or a combination of these gases, may be used. As the second modifying agent, one or more of these gases may be used. Further, when using these gases as the second modifying agent, the second termination containing Si as the predetermined element and constituted by the second halogen element (for example, a Si—Cl termination, a Si—F termination, etc.) are formed.

After forming the second termination on the surface of the wafer 200 (the inner surface of the recess 300), the valve 243c is closed to stop the supply of the second modifying agent into the process chamber 201. Then, the inside of the process chamber 201 is vacuum-exhausted to remove a gaseous substance and the like remaining in the process chamber 201 from the inside of the process chamber 201. At this time, the valves 243e and 243f are opened to allow an inert gas to be supplied into the process chamber 201 via the nozzles 249a and 249b, respectively. The inert gas supplied from the nozzles 249a and 249b acts as a purge gas, whereby the space where the wafer 200 is placed, that is, the inside of the process chamber 201, is purged (purging).

### Step C

After Step B is completed, a precursor containing Si as a predetermined element is supplied to the wafer 200 in the process chamber 201, that is, the wafer 200 after the second termination is formed on the inner surface of the recess 300.

Specifically, the valve 243d is opened to allow the precursor to flow through the gas supply pipe 232d. A flow rate of the precursor is regulated by the MFC 241d, and the precursor is supplied into the process chamber 201 via the nozzle 249b and is exhausted via the exhaust port 231a. In this operation, the precursor is supplied to the wafer 200 (supply of precursor). At this time, the valves 243e and 243f may be opened to allow an inert gas to be supplied into the process chamber 201 via the nozzles 249a and 249b, respectively.

A process condition when the precursor is supplied in this step is exemplified as follows:
Processing temperature: 400 to 900 degrees C., specifically 500 to 800 degrees C., more specifically 600 to 750 degrees C.
Processing pressure: 1 to 2,666 Pa, specifically 10 to 1,333 Pa
Supply flow rate of precursor: 0.001 to 2 slm, specifically 0.1 to 1 slm
Supply time of precursor: 0.5 to 60 seconds, specifically 1 to 30 seconds

Other process conditions may be the same as those used when supplying the pretreatment reactant during the pre-flow.

By supplying the precursor containing Si to the wafer 200 under the above-described process condition, the precursor may be mainly adsorbed on locations of the surface of the wafer 200 where at least one selected from the group of the first termination and the second termination is not formed (in other words, locations where both the first termination region and the second termination region are not formed, that is, adsorption sites remaining on the surface of the wafer 200 which are not terminated with either the first halogen element or the second halogen element) to form a deposited layer (hereinafter sometimes referred to as a “first layer”) containing a predetermined element (Si) (see FIG. 5C). At this time, the first halogen element constituting the first termination and the second halogen element constituting the second termination respectively react with Si containing a dangling bond generated from the precursor, such that the first halogen element and the second halogen element are at least partially desorbed from the surface of the wafer 200.

Further, in the following, the first layer, which is the deposited layer, may refer to a layer containing a predetermined element, which includes the first halogen element constituting the first termination and the second halogen element constituting the second termination, in addition to the predetermined element adsorbed on the adsorption sites. Further, the first layer may further contain other elements (for example, carbon (C), nitrogen (N), a third halogen element described below, other impurities, etc.) other than the predetermined element contained in the precursor.

As the precursor, silane-based gases such as a monosilane (SiH₄) gas, a disilane (Si₂H₆) gas, and a trisilane (Si₃H₈) gas may be used.

Further, as the precursor, a gas containing a third halogen element in addition to the predetermined element may be used. That is, when the predetermined element is Si, a halosilane gas may be used as the precursor. As the third halogen element, at least one selected from the group of Cl, F, Br, and I may be used. The third halogen element contained in the precursor, the second halogen element contained in the second modifying agent, and the first halogen element contained in the first modifying agent may be the same element, or may be different from one another, or one of them may be different from the others. However, the precursor is a gas which is different in molecular structure from the first modifying agent and the second modifying agent. Further, as the precursor containing the third halogen element, chlorosilane-based gas such as a hexachlorodisilane (Si₂Cl₆) gas, an octachlorotrisilane (Si₃Cl₈) gas, a monochlorodisilane (Si₂H₅Cl) gas, a dichlorodisilane (Si₂H₄Cl₂) gas, a trichlorodisilane (Si₂H₃Cl₃) gas, a tetrachlorodisilane (Si₂H₂Cl₄) gas, a monochlorotrisilane (Si₃H₅Cl) gas, and a dichlorotrisilane (Si₃H₄Cl₂) gas, which contain any Si—Si bond (that is, any bond between predetermined elements) in one molecule, or other halosilane-based gases containing a molecular structure in which Cl atoms in the molecular structure of these chlorosilane-based gases are substituted with atoms of other halogen elements may be used. Further, as the precursor, chlorosilane-based gases such as a dichlorosilane (SiH₂Cl₂) gas, which do not contain any Si—Si bond in one molecule, or other halosilane-based gases in which Cl atoms in the molecular structure of these chlorosilane-based gases are substituted with atoms of other halogen elements may be used. Further, as the precursor containing the third halogen element, a gas that is a combination of the above-described halosilane gases as the precursor may be used.

Further, as the precursor, for example, aminosilane-based gases such as a tetrakis(dimethylamino)silane (Si[N(CH₃)₂]₄) gas, a tris(dimethylamino)silane (Si[N(CH₃)₂]₃H) gas, a bis(diethylamino)silane (Si[N(C₂H₅)₂]₂H₂) gas, a bis(tert-butylamino)silane (SiH₂[NH(C₄H₉)]₂) gas, and a (diisopropylamino)silane (SiH₃[N(C₃H₇)₂]) gas, or a combination of these gases may be used.

When using a gas containing a predetermined element as the second modifying agent, a gas whose thermal decomposition temperature is relatively lower than that of the second modifying agent (that is, a gas that is relatively low in energy for decomposing molecules than the second modifying agent) may be used as the precursor. By using the gas with the lower thermal decomposition temperature as the precursor, formation rate of a layer containing a predetermined element may be increased in step C. Further, by using a gas with a high thermal decomposition temperature as the second modifying agent containing the predetermined element, multi-adsorption of the predetermined element on the inner surface of the recess 300, which occurs due to excessive thermal decomposition of the second modifying agent, may be suppressed, thereby preventing deterioration of step coverage. As a combination with such a thermal decomposition temperature relationship, for example, a gas containing no Si—Si bonds in one molecule may be used as the second modifying agent and a gas containing Si—Si bonds in one molecule may be used as the precursor. In this case, the Si—Si bonds contained in the precursor are broken by thermal decomposition to generate Si with a highly reactive dangling bond, thereby increasing the formation rate of the layer containing Si in step C.

When using such a combination of gases as the second modifying agent and the precursor, the processing temperature in step B may be set to a temperature at which the second modifying agent is not substantially thermally decomposed, and the processing temperature in step C may be set to a temperature at which the precursor is substantially thermally decomposed.

One or more of these gases may be used as the precursor.

After forming the first layer on the surface of the wafer 200 (the inner surface of the recess 300), the valve 243d is closed to stop the supply of the precursor into the process chamber 201. Then, the inside of the process chamber 201 is vacuum-exhausted to remove a gaseous substance and the like remaining in the process chamber 201 from the inside of the process chamber 201. At this time, the valves 243e and 243f are opened to allow an inert gas to be supplied into the process chamber 201 via the nozzles 249a and 249b, respectively. The inert gas supplied from the nozzles 249a and 249b acts as a purge gas, whereby the space where the wafer 200 is placed, that is, the inside of the process chamber 201, is purged (purging).

### Step D

After step C is completed, a reactant as a film-forming agent that reacts with the first layer is supplied to the wafer 200 in the process chamber 201, that is, the wafer 200 after the first layer is formed over the inner surface of the recess 300.

Specifically, the valve 243a is opened to allow the reactant to flow through the gas supply pipe 232a. A flow rate of the reactant is regulated by the MFC 241a, and the reactant is supplied into the process chamber 201 via the nozzle 249a and is exhausted via the exhaust port 231a. In this operation, the reactant is supplied to the wafer 200 (supply of reactant). At this time, the valves 243e and 243f may be opened to allow an inert gas to be supplied into the process chamber 201 via the nozzles 249a and 249b, respectively.

A process condition when the reactant is supplied in this step is exemplified as follows:
Processing pressure: 1 to 4,000 Pa, specifically 10 to 1,000 Pa
Supply flow rate of reactant: 0.1 to 10 slm, specifically 1 to 5 slm
Supply time of reactant: 1 to 120 seconds, specifically 10 to 60 seconds

Other process conditions may be the same as those used when supplying the pretreatment reactant during the pre-flow.

By supplying the reactant to the wafer 200 under the above-described process condition, at least a portion of the first layer formed over the inner surface of the recess 300 reacts with the reactant and is modified. As a result, a second layer, which is a modified layer of the first layer, is formed over the inner surface of the recess 300. The second layer is a predetermined element-containing layer (Si-containing layer). When forming the second layer, at least some of impurities such as the halogen elements contained in the first layer (for example, the first halogen element constituting the first termination, the second halogen element constituting the second termination, the third halogen element contained in the precursor, etc.) are desorbed, as a gaseous substance, from the first layer in the process of the modifying reaction of the first layer, and are discharged from the inside of the process chamber 201. As a result, the second layer becomes a layer containing fewer impurities such as halogen elements than the first layer formed in step C.

However, even in this step, without completely desorbing the first halogen element constituting the first termination and the second halogen element constituting the second termination contained in the first layer, at least one selected from the group of the first termination and the second termination may remain on at least a portion of the upper surface, at least a portion of the inner surface, or at least both a portion of the upper surface and a portion of the inner surface of the recess 300 treated in step A of the subsequent film-forming cycle. As described above, by allowing at least one selected from the group of the first termination and the second termination to remain in this step, the adsorption suppressing effect on the precursor in step C of the subsequent film-forming cycle may be further enhanced. By leaving the first termination and the second termination as described above, step coverage of a film formed over the inner surface of the recess 300 may be further improved, as described below.

As the reactant used in this step, a nitrogen (N)-containing gas (N-containing substance) may be used. In the embodiments of the present disclosure, the same gas as the hydrogen nitride-based gas used in the pre-flow is used as the reactant. For example, when using the above-described silane-based gas as the precursor and the N-containing gas as the reactant, a silicon nitride layer (SiN layer) is formed as the second layer over the surface of the wafer 200. In this case, the reactant acts as a nitridation source (nitrogen source).

Further, as the reactant, for example, an oxygen (O)- and H-containing gas (O- and H-containing substance) may be used. As the O- and H-containing gas, water vapor (H₂O gas), a hydrogen peroxide (H₂O₂) gas, hydrogen (H₂) gas+oxygen (O₂) gas, H₂ gas+ozone (O₃) gas, etc. may be used. That is, as the O- and H-containing gas, O-containing gas+H-containing gas may also be used. In this case, instead of the H₂ gas, a deuterium (²H₂) gas may also be used as the H-containing gas.

In the present disclosure, description of two gases such as “H₂ gas+O₂ gas” together refers to a mixed gas of H₂ gas and O₂ gas. When supplying the mixed gas, the two gases may be mixed (pre-mixed) in a supply pipe and then supplied into the process chamber 201, or the two gases may be supplied separately from different supply pipes into the process chamber 201 and then mixed (post-mixed) in the process chamber 201.

Further, as the reactant, an O-containing gas (O-containing substance) may be used. As the O-containing gases, an O₂ gas, an ozone (O3) gas, a nitrous oxide (N₂O) gas, a nitric oxide (NO) gas, a nitrogen dioxide (NO₂) gas, a carbon monoxide (CO) gas, a carbon dioxide (CO₂) gas, etc. may be used. For example, when using the above-described silane-based gas as the precursor and the O- and H-containing gas or the O-containing gas as the reactant, a silicon oxide layer (SiO layer) is formed as the second layer over the surface of the wafer 200. In this case, the reactant acts as an oxidation source (oxygen source).

Further, as the reactant, a H-containing gas (H-containing substance) may be used. As the H-containing gas, in addition to the above-described hydrogen nitride-based gas and O- and H-containing gas, a H₂ gas or the like may be used. By using the H-containing gas as the reactant, impurities such as halogen elements remaining in the first layer may be more efficiently desorbed and removed from the layer. Further, for example, by using the H₂ gas as the reactant, the first layer may be modified into the second layer that does not contain N or O.

One or more of these gases may be used as the reactant. Further, in the embodiments of the present disclosure, a case is described in which the pretreatment reactant used in step A and the reactant used in step D are the same gas, but the present disclosure is not limited thereto, and both the pretreatment reactant used in step A and the reactant used in step D may be different gases. For example, both of them may be different N-containing gases, or may be different O- and H-containing gases or O-containing gases.

After changing the first layer formed over the surface of the wafer 200 (the inner surface of the recess 300) into the second layer, the valve 243a is closed to stop the supply of the reactant into the process chamber 201. Then, the inside of the process chamber 201 is vacuum-exhausted to remove a gaseous substance and the like remaining in the process chamber 201 from the inside of the process chamber 201. At this time, the valves 243e and 243f are opened to allow an inert gas to be supplied into the process chamber 201 via the nozzles 249a and 249b, respectively. The inert gas supplied from the nozzles 249a and 249b acts as a purge gas, whereby the space where the wafer 200 is placed, that is, the inside of the process chamber 201, is purged (purging).

### [Performing Predetermined Number of Times]

By performing a cycle n times (n is an integer of 1 or 2 or more), the cycle including non-simultaneously, that is, without synchronization, performing the steps A to D in this order, it is possible to form a film with a desired composition over the surface of the wafer 200 (the inner surface of the recess 300) (see FIG. 5D). For example, when using the above-described Si-containing gas as the precursor and the above-described N-containing gas as the reactant, a silicon nitride film (SiN film) is formed over the surface of the wafer 200. Further, when using the above-described Si-containing gas as the precursor and the above-described O-containing gas as the reactant, a silicon oxide film (SiO film) is formed over the surface of the wafer 200. The above-described cycle may be performed a plurality of times. That is, a thickness of the second layer formed per cycle may be set to be smaller than a desired film thickness, and the above-described cycle may be performed a plurality of times until a thickness of the film formed by stacking second layers reaches the desired film thickness.

### (After-Purge and Returning to Atmospheric Pressure)

After the film-forming process is completed, an inert gas acting as a purge gas is supplied into the process chamber 201 from each of the nozzles 249a and 249b and is exhausted via the exhaust port 231a. Thus, the inside of the process chamber 201 is purged and a gas, reaction by-products, and the like remaining in the process chamber 201 are removed from the inside of the process chamber 201 (after-purge). Thereafter, the internal atmosphere of the process chamber 201 is substituted with an inert gas (substitution of inert gas) and the internal pressure of the process chamber 201 is returned to the atmospheric pressure (returning to atmospheric pressure).

### (Boat Unloading and Wafer Discharging)

Thereafter, the seal cap 219 is moved down by the boat elevator 115 to open the lower end of the manifold 209. Then, the processed wafers 200 supported by the boat 217 are unloaded from the lower end of the manifold 209 to the outside of the reaction tube 203 (boat unloading). After the boat unloading, the shutter 219s is moved and the lower end opening of the manifold 209 is sealed by the shutter 219s via the O-ring 220c (shutter closing). The processed wafers 200 are unloaded from the reaction tube 203 and are then discharged from the boat 217 (wafer discharging).

### (3) Effects of the Embodiments

According to the embodiments of the present disclosure, one or more effects set forth below may be achieved.

(a) By performing step A of supplying the first modifying agent containing the first halogen element to the wafer 200 and step B of supplying the second modifying agent containing the second halogen element, which is different in molecular structure from the first modifying agent, to the wafer 200, it is possible to improve the step coverage of the film formed over the inner surface of the recess 300, as compared to a case where a single halogen element-containing modifying agent is used.

(b) Further, by performing step A of supplying the first modifying agent containing the first halogen element to the wafer 200 and step B of supplying the second modifying agent containing the second halogen element, which is different in molecular structure from the first modifying agent, to the wafer 200, it is possible to improve the step coverage of the film formed over the inner surface of the recess 300 while suppressing an increase in the supply time of modifying agent, as compared to a case where a single halogen element-containing modifying agent is used.

A gas supplied to the wafer 200 with the recess 300 tends to easily reach the opening side 301 and less likely to reach the deep side 302. Such a tendency becomes noticeable when the supply time of gas is relatively short. In the embodiments, in step A, the first modifying agent which is lower in rate of adsorption on the surface of the wafer 200 than the second modifying agent supplied in step B is supplied such that the supply time of the first modifying agent is set to be shorter than the supply time of the second modifying agent in step B. As a result, in step A, the first modifying agent may be more easily adsorbed on the opening side 301 of the recess 300 to form the first termination (see FIG. 5A).

On the other hand, in step B, the second modifying agent which is higher in rate of adsorption on the surface of the wafer 200 than the first modifying agent supplied in step A, that is, the second modifying agent, which is relatively shorter in time for the formation of the second termination, is supplied. A gas with a high rate of adsorption, which is supplied to the wafer 200 with the recess 300, tends to be easily adsorbed on the opening side 301 and less likely to reach the deep side 302. However, due to the adsorption suppressing effect of the first termination on the second modifying agent, in step B, the second modifying agent passes through the opening side 301 where the first termination is formed, and is preferentially adsorbed on the deep side 302 to form the second termination (see FIG. 5B). As a result, in Step B, even in a case where the supply time of the second modifying agent is relatively short, the second modifying agent may be easily adsorbed on the deep side 302 of the recess 300 to form the second termination.

Further, as described above, the gas supplied to the wafer 200 with the recess 300 tends to easily reach the opening side 301 and less likely to reach the deep side 302, but when the supply time of gas is relatively long, the gas may easily reach the deep side 302 as well. In the embodiments of the present disclosure, in step B, the supply time of the second modifying agent is set to be longer than the supply time of the first modifying agent in step A. This makes it easier for the second modifying agent to be adsorbed on the deep side 302 of the recess 300 to form the second termination in step B.

As described above, by performing steps A and B, the first termination may be formed on the opening side 301 of the recess 300, and the second termination may be formed on the deep side 302 of the recess 300.

In the subsequent step C, due to the adsorption suppressing effects of the first termination and the second termination on the precursor, the precursor is adsorbed on locations where at least one selected from the group of the first termination and the second termination is not formed, to form the deposited layer (first layer) containing Si. Since the precursor supplied at this time also tends to easily reach the opening side 301 and less likely to reach the deep side 302, there is a possibility that the first layer is formed to be biased toward the opening side 301. However, in the embodiments, since the first termination formed on the opening side 301 is larger in adsorption suppressing effect on the precursor than the second termination region formed on the deep side 302, it is possible to sufficiently suppress the adsorption of a relatively large amount of the precursor that reach the opening side 301. On the other hand, although the second termination formed on the deep side 302 is smaller in adsorption suppressing effect on the precursor than the first termination, since a relatively small amount of the precursor reaches the deep side 302, it is possible to sufficiently suppress the adsorption of the precursor. As described above, in the embodiments, the first modifying agent and the second modifying agent are supplied to form the first termination, which is relatively large in adsorption suppressing effect on the precursor, on the opening side 301 and form the second termination, which is relatively small in adsorption suppressing effect on the precursor, on the deep side 302, such that the precursor may uniformly reach the entire inner surface of the recess 300. As a result, it is possible to form a film with excellent step coverage.

(c) Further, by setting the supply time of the first modifying agent which is lower in rate of adsorption on the surface of the wafer 200 than the second modifying agent, that is, the first modifying agent for which a time for forming the first termination is relatively long, to be shorter than the supply time of the second modifying agent, it is possible to minimize an increase in the supply time of modifying agent (a total supply time of the first modifying agent and the second modifying agent).

(d) In step A, by supplying the first modifying agent that does not contain a predetermined element (Si), it is possible to form the first termination with a large adsorption suppressing effect on the precursor. In step B, by supplying the second modifying agent containing the predetermined element, it is possible to form the second termination containing the predetermined element with an adsorption suppressing effect on the precursor.

(e) In step B, a gas containing Si and containing no bond between predetermined elements (Si) in one molecule is supplied as the second modifying agent, and in step C, a gas containing bonds between predetermined elements in one molecule is supplied as the precursor. As described above, in step C, by supplying the precursor that is more easily thermally decomposed than the second modifying agent and more likely to generate a predetermined element with a dangling bond, it is possible to improve a deposition rate, as compared with a case where the second modifying agent is supplied to form a predetermined element-containing layer (first layer).

(f) In step C, the first halogen element constituting the first termination and the second halogen element constituting the second termination may be desorbed by reacting with a predetermined element (Si) with a dangling bond generated from the precursor, it is possible to suppress deterioration of the step coverage of a film, as will be described below. As an example, in a case where both the first halogen element and the second halogen element are Cl and the precursor is a Si₂Cl₆ gas, in step C, these Cl's bond to Si (with a dangling bond) in SiCl₂ generated by thermal decomposition of the Si₂Cl₆ gas and are desorbed from the respective regions. This allows SiCl₂ with high reactivity (easily subjected to multi-adsorption) to be changed to SiCl₄ with low reactivity (hardly subjected to multi-adsorption). As a result, it is possible to reduce an amount of SiCl₂ in the process chamber 201 to an appropriate amount, thereby suppressing deterioration of the step coverage due to multi-adsorption of SiCl₂.

(g) In step C, by supplying a gas containing the third halogen element as the precursor, it is possible to shorten a cycle time, thereby improving a productivity of the film-forming process, as will be described below. In step C, by supplying a gas containing the third halogen element as the precursor, the deposited layer (first layer) containing the third halogen element may be formed on the inner surface of the recess 300. In step D, the first layer is modified to desorb the third halogen element from the first layer. The third halogen element desorbed from the first layer may be re-adsorbed on the inner surface of the recess 300 to form a portion of the first termination in the subsequent film-forming cycle. As a result, it is possible to shorten the cycle time, thereby improving the productivity of the film-forming process.

(h) By supplying the precursor supplied in step C and the first modifying agent and the second modifying agent supplied in steps A and B, respectively, to the wafer 200 via the same nozzle (the nozzle 249b), it is possible to suppress adhesion/deposition of the precursor within the nozzle 249b.

(i) The above-described effects may be similarly obtained even when a predetermined substance (gaseous substance or liquid substance) arbitrarily selected from the above-described various modifying agents, various precursors, various reactants, and various inert gases is used.

### (4) Modifications

The processing sequence in the embodiments of the present disclosure may be changed as shown in the following modifications. These modifications may be combined arbitrarily. Unless otherwise described, processing procedures and process conditions in each step of each modification may be the same as the processing procedures and process conditions in each step of the above-described processing sequence.

### First Modification

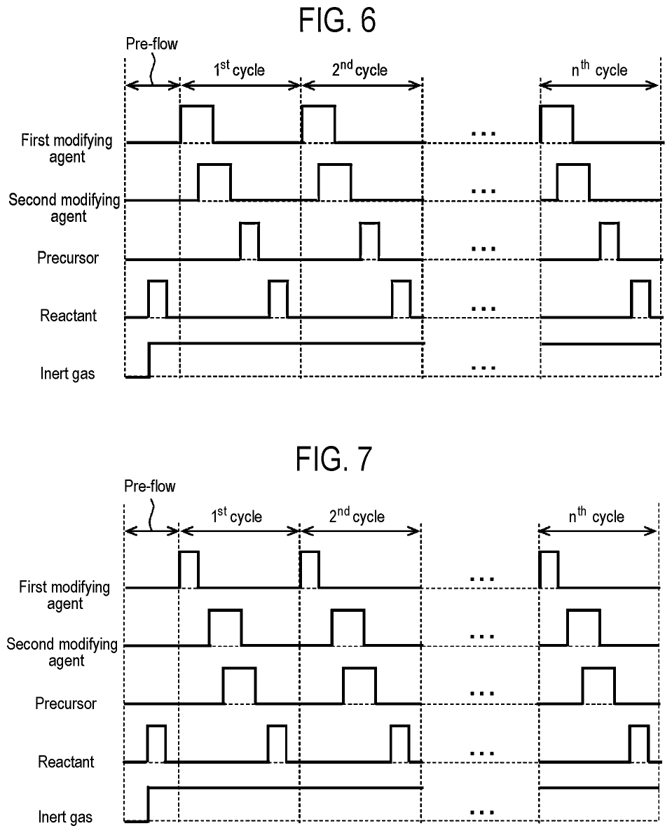

As shown in FIG. 6 and a processing sequence shown below, steps A, B, C, and D may be performed in this order while at least partially overlapping execution periods of the steps A and B.

Reactant (pre-flow)→(First modifying agent→First modifying agent+Second modifying agent→Second modifying agent→Purge→Precursor→Purge→Reactant→Purge)×n

In the first modification, in addition to the above-described effects, it is possible to shorten the cycle time, thereby improving the productivity of the film-forming process.

### Second Modification

As shown in FIG. 7 and a processing sequence shown below, steps A, B, C, and D may be performed in this order while at least partially overlapping execution periods of the steps B and C.

Reactant (pre-flow)→(First modifying agent→Second modifying agent→Second modifying agent+Precursor→Precursor→Purge→Reactant→Purge)×n

In the second modification, in addition to the above-described effects, it is possible to shorten the cycle time, thereby improving the productivity of the film-forming process.

### Third Modification

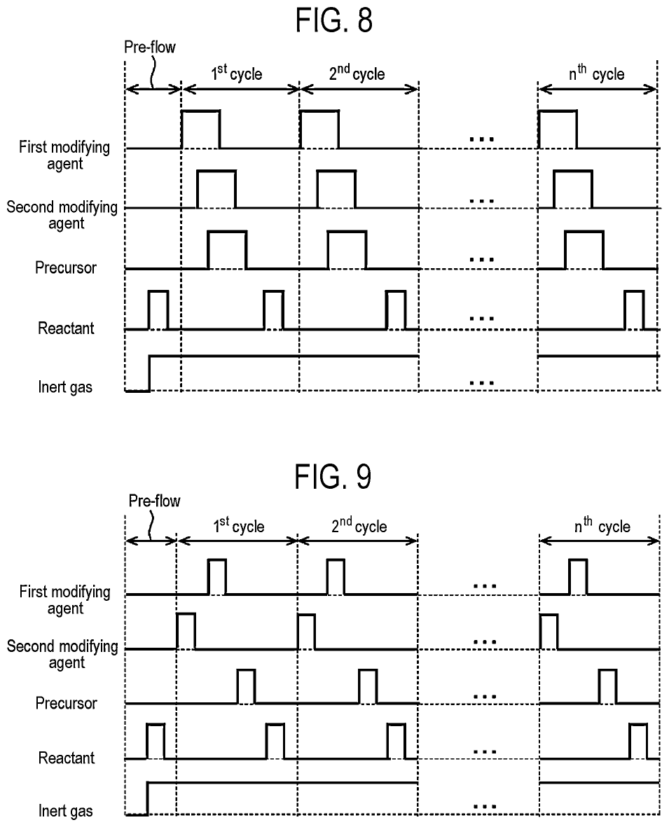

As shown in FIG. 8 and a processing sequence shown below, steps A, B, C, and D may be performed in this order while at least partially overlapping execution periods of steps A, B, and C.

Reactant (pre-flow)→(First modifying agent→First modifying agent+Second modifying agent→First modifying agent+Second modifying agent+Precursor→Second modifying agent+Precursor→Precursor→Purge→Reactant→Purge)×n

Further, in this modification, between the start of step A and the end of step C, in a case where the steps A and B are completed by the time the step C is completed, it is possible to overlap execution periods of steps A, B, and C in any manner.

In the third modification, in addition to the above-described effects, it is possible to further shorten the cycle time, thereby further improving the productivity of the film-forming process.

### Fourth Modification

As shown in FIG. 9 and a processing sequence shown below, steps A to D may be performed non-simultaneously in the order of steps B, A, C, and D.

Reactant (pre-flow)→(Second modifying agent→Purge→First modifying agent→Purge→Precursor→Purge→Reactant→Purge)×n

In the fourth modification, it is possible to at least partially obtain the above-described effects.

### Fifth Modification

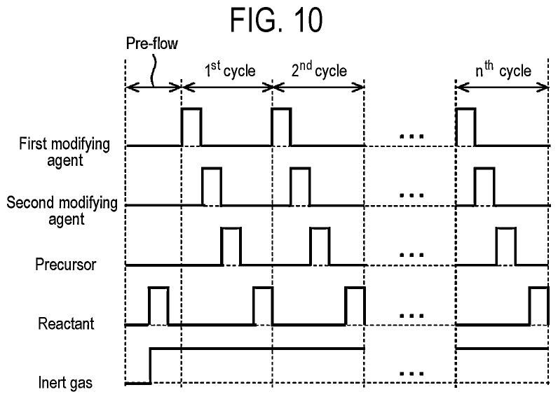

As shown in FIG. 10 and a processing sequence shown below, the purge performed after each of steps A, B, and D may be omitted.

Reactant (pre-flow)→(First modifying agent→Second modifying agent→Precursor→Purge→Reactant)×n

In the fifth modification, since the purge is performed between the step C and the step D, while suppressing generation of particles due to a reaction between the precursor and the reactant to avoid deterioration in film quality, in addition to the above-described effects, it is possible to shorten the cycle time, thereby improving the productivity of the film-forming process.

### Sixth Modification

As shown in the processing sequence shown below, cycle B that performs step A (supply of first modifying agent) may also be performed each time cycle A where the step A (supply of first modifying agent) is omitted is performed a predetermined number of times (m times, where m is an integer of 1 or 2 or more). Super cycle C including cycle A and cycle B is performed a predetermined number of times (n times, where n is an integer of 1 or 2 or more) until a thickness of a film formed over the wafer 200 reaches a predetermined thickness.

Reactant (pre-flow)→[(First modifying agent→Purge→Second modifying agent→Purge→Precursor→Purge→Reactant→Purge)→(Second modifying agent→Purge→Precursor→Purge→Reactant→Purge)×m]×n

The sixth modification 6 may be performed in a case where the adsorption suppressing effect of the first termination formed in the step A on the precursor may be maintained while the cycle A in which step A is omitted is performed m times. As described above, by forming the film through the cycle including the cycle A in which the step A is omitted, in addition to the above-described effects, it is possible to further shorten the cycle time by omitting a portion of the step A.

### Other Embodiments of the Present Disclosure

The embodiments of the present disclosure are specifically described above. However, the present disclosure is not limited to the above-described embodiments, and various changes may be made without departing from the gist thereof.

For example, in the above-described embodiments, cases are described above in which the steps A and B are performed in a non-plasma atmosphere. However, the present disclosure is not limited to such embodiments. For example, steps A and B may be performed in a plasma atmosphere where the halogen element-containing gases exemplified as the first modifying agent and the second modifying agent are plasma-excited. Also in this case, the same effects as in the above-described embodiments may be obtained. When using a predetermined element-containing gas as the second modifying agent, the first modifying agent may be plasma-excited, while the second modifying agent may be used in a state where the second modifying gas is not plasma-excited (in a non-plasma state). By using the second modifying agent, which is the predetermined element-containing gas, in the non-plasma state, it is possible to suppress the second modifying agent decomposed by plasma excitation from being multi-deposited on the wafer 200 and deteriorating film properties such as the step coverage.

For example, in the above-described embodiments, cases are described as examples in which the predetermined element contained in the second modifying agent or the precursor is Si. However, the present disclosure is not limited to such embodiments. For example, the predetermined element may include metal elements such as titanium (Ti), zirconium (Zr), hafnium (Hf), tantalum (Ta), niobium (Nb), aluminum (Al), molybdenum (Mo), tungsten (W), and germanium (Ge). In these cases, a halogen compound gas containing these metal elements may be used as the second modifying agent or the precursor. In particular, when using a gas containing a group IV element such as Ti, Zr, or Hf or a group XIV element such as Ge as the second modifying agent, it is possible to use a compound gas in which three or more halogen elements are bonded to a predetermined element, such as a titanium tetrachloride (TiCl₄) gas, a zirconium tetrachloride (ZrCl₄) gas, a hafnium tetrachloride (HfCl₄) gas, or a germanium tetrachloride (GeCl₄) gas. Even in these cases, the same effects as in the above-described embodiments may be obtained.

For example, in the above-described embodiments, cases are described above in which the step A is mainly performed first in the film formation. However, the present disclosure is not limited to such embodiments. For example, as long as the execution period of step A and the execution period of step D do not overlap each other, step A may be performed at any time. Even in this case, it is possible to at least partially obtain the above-described effects.

For example, in the above-described embodiments, cases are described in which the precursor, the first modifying agent, and the second modifying agent are supplied to the wafer 200 via the same nozzle (the nozzle 249b). However, the present disclosure is not limited to such embodiments. For example, the precursor, and the first modifying agent or the second modifying agent may be supplied to the wafer 200 via the nozzle 249b. Even in this case, the same effects as in the above-described embodiments may be obtained.

For example, in the above-described embodiments, cases are described above in which the Si film is formed as a base on the surface of the wafer 200. However, the present disclosure is not limited to such embodiments. For example, an oxide film such as a SiO film or a nitride film such as a SiN film may be formed as a base on the surface of the wafer 200. Even in these cases, the same effects as in the above-described embodiments may be obtained.

Further, a step coverage of a film containing a predetermined element formed over the inner surface of the recess 300 may be determined by substituting, for example, a thickness T_{TOP} of a film formed on an upper side (edge) of the recess 300 and a thickness T_{BOT} of a film formed over a bottom surface of the recess 300, into the following equation (1).

$$Step coverage ( \% ) = [ {T}_{BOT} / {T}_{TOP} ] \times 100 \qquad Equation ( 1 )$$

However, the step coverage in the present disclosure is not limited to this calculation method, and may include other characteristics related to thickness uniformity of a film formed on steps of a three-dimensional structure such as the recess 300, or other indicators indicating the same.

Further, the improvement in the step coverage is not limited to a case in which the thickness of the film formed over the steps approaches to uniformity, but may include a case where a distribution of the film thickness approaches a desired distribution of film thickness (for example, a case where the step coverage calculated in the equation (1) approaches a desired value in a range exceeding 100%) when performing film formation in which the film thickness increases from the upper side toward the bottom side within the recess, such as in bottom-up film formation within the recess.

Recipes used in each process may be provided individually according to processing contents and may be recorded and stored in the memory 121c via a telecommunication line or the external memory 123. Moreover, at the beginning of each process, the CPU 121a may properly select an appropriate recipe from the recipes recorded and stored in the memory 121c according to the processing contents. Thus, it is possible for a single substrate processing apparatus to form films of various kinds, composition ratios, qualities, and thicknesses with enhanced reproducibility. Further, it is possible to reduce an operator's burden and to quickly start each process while avoiding an operation error.

The recipes described above are not limited to newly-provided ones but may be provided, for example, by modifying existing recipes that are already installed in the substrate processing apparatus. Once the recipes are modified, the modified recipes may be installed in the substrate processing apparatus via a telecommunication line or a recording medium storing the recipes. In addition, the existing recipes already installed in the existing substrate processing apparatus may be directly modified by operating the input/output device 122 of the substrate processing apparatus.

Examples where a film is formed by using a batch-type substrate processing apparatus capable of processing a plurality of substrates at a time are described above in the above-described embodiments. The present disclosure is not limited to the above-described embodiments, but may be suitably applied, for example, to a case where a film is formed by using a single-wafer type substrate processing apparatus capable of processing a single substrate or several substrates at a time. In addition, examples in which the film is formed by using a substrate processing apparatus provided with a hot-wall-type process furnace are described above in the above-described embodiments. The present disclosure is not limited to the above-described embodiments, but may be suitably applied to a case where a film is formed by using a substrate processing apparatus provided with a cold-wall-type process furnace.

Even in the case of using these substrate processing apparatuses, each process may be performed according to the same processing procedures and process conditions as those in the above-described embodiments and modifications, and the same effects as in the above-described embodiments and modifications are achieved.

The above-described embodiments and modifications may be used in proper combination. Processing procedures and process conditions used in this case may be the same as, for example, the processing procedures and the process conditions in the above-described embodiments and modifications.

According to the present disclosure in some embodiments, it is possible to improve a step coverage of a film formed over a substrate.

While certain embodiments are described above, these embodiments are presented by way of example, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method of processing a substrate, comprising:
forming a film containing a predetermined element over an inner surface of a recess formed on a surface of the substrate by performing a cycle a predetermined number of times, the cycle including performing:
(a) supplying a first modifying agent containing a first halogen element to the substrate;
(b) supplying a second modifying agent containing a second halogen element, which is different in molecular structure from the first modifying agent, to the substrate;
(c) after starting (a) and (b), forming a deposited layer containing the predetermined element by supplying a precursor containing the predetermined element, which is different in molecular structure from the first modifying agent and the second modifying agent, to the substrate; and
(d) after (c), supplying a reactant, which reacts with the deposited layer, to the substrate.

2. The method of claim 1, wherein the first modifying agent does not contain the predetermined element, and the second modifying agent contains the predetermined element.

3. The method of claim 1, wherein the first modifying agent is lower in a rate of adsorption on the inner surface of the recess than the second modifying agent.

4. The method of claim 1, wherein in the cycle, (a) is performed for a shorter time than (b).

5. The method of claim 1, wherein in (a), a first termination terminated with the first halogen element is formed on the inner surface of the recess.

6. The method of claim 5, wherein in (b), a second termination terminated with the second halogen element is formed on the inner surface of the recess.

7. The method of claim 6, wherein the first termination is greater in adsorption-suppressing effect on the precursor than the second termination.

8. The method of claim 6, wherein in (b), the second termination is formed such that at least a portion of a region on the inner surface where the second termination is formed overlaps a region on the inner surface where the first termination is formed.

9. The method of claim 6, wherein the second modifying agent is a modifying agent that contains the predetermined element, and
wherein in (b), the second termination containing the predetermined element is formed on the inner surface of the recess.

10. The method of claim 6, wherein in (b), the formation of the second termination is more suppressed in a region where the first termination is formed than in a region on the inner surface of the recess where the first termination is not formed.

11. The method of claim 6, wherein in (c), the first halogen element constituting the first termination and the second halogen element constituting the second termination are desorbed by reacting with atoms of the predetermined element containing a dangling bond generated from the precursor.

12. The method of claim 6, wherein in (c), adsorption of the predetermined element is more suppressed on a region of the inner surface of the recess where at least one selected from the group of the first termination and the second termination is formed than on a region of the inner surface of the recess where both the first termination and the second termination are not formed.

13. The method of claim 1, wherein the second modifying agent is a gas that contains the predetermined element and does not contain a bond between the predetermined elements in one molecule, and the precursor is a gas that contains the bond between the predetermined elements in one molecule.

14. The method of claim 1, wherein the precursor is a gas that contains a third halogen element.

15. The method of claim 1, wherein in the cycle, (a) is started before (b).

16. The method of claim 1, wherein in the cycle, (a) and (b) are performed such that periods of (a) and (b) overlap at least partially.

17. The method of claim 1, wherein in the cycle, (b) and (c) are performed such that periods of (b) and (c) overlap at least partially.

18. A method of manufacturing a semiconductor device, comprising the method of claim 1.

19. A non-transitory computer-readable recording medium storing a program that causes, by a computer, a substrate processing apparatus to perform a process comprising:
forming a film containing a predetermined element over an inner surface of a recess formed on a surface of a substrate by performing a cycle a predetermined number of times, the cycle including performing:
(a) supplying a first modifying agent containing a first halogen element to the substrate;
(b) supplying a second modifying agent containing a second halogen element, which is different in molecular structure from the first modifying agent, to the substrate;
(c) after starting (a) and (b), forming a deposited layer containing the predetermined element by supplying a precursor containing the predetermined element, which is different in molecular structure from the first modifying agent and the second modifying agent, to the substrate; and
(d) after (c), supplying a reactant, which reacts with the deposited layer, to the substrate.

20. A substrate processing apparatus comprising:
a first modifying agent supply system configured to supply a first modifying agent containing a first halogen element to a substrate including a recess formed on a surface of the substrate;
a second modifying agent supply system configured to supply a second modifying agent containing a second halogen element, which is different in molecular structure from the first modifying agent, to the substrate;
a precursor supply system configured to supply a precursor containing a predetermined element, which is different in molecular structure from a first modifying agent and the second modifying agent, to the substrate;
a reactant supply system configured to supply a reactant to the substrate; and
a controller configured to be capable of controlling the first modifying agent supply system, the second modifying agent supply system, the precursor supply system, and the reactant supply system to perform a process including:
forming a film containing the predetermined element over an inner surface of the recess by performing a cycle a predetermined number of times, the cycle including performing:
(a) supplying the first modifying agent to the substrate;
(b) supplying the second modifying agent to the substrate;
(c) after starting (a) and (b), forming a deposited layer containing the predetermined element by supplying the precursor to the substrate; and
(d) after (c), supplying the reactant, which reacts with the deposited layer, to the substrate.
